(19) United States
(12) Patent Application Publication
(10) Pub. No.: US 2025/0309095 A1
(43) Pub. Date: Oct. 2, 2025

(54) CAPACITOR STRUCTURE AND METHOD FOR FABRICATING THE SAME

(71) Applicant: Taiwan Semiconductor Manufacturing Company, Ltd., Hsinchu (TW)

(72) Inventors: Meng-Hsien Lin, Tainan City (TW); Shih-Rong Yang, Hsinchu (TW); Ming-Tsong Wang, Taipei City (TW); Ko Chun Liu, Miaoli County (TW); Hsing-Chih Lin, Tainan City (TW); Jen-Cheng Liu, Hsin-Chu City (TW); Dun-Nian Yaung, Taipei City (TW)

(73) Assignee: Taiwan Semiconductor Manufacturing Company, Ltd., Hsinchu (TW)

(21) Appl. No.: 18/623,017

(22) Filed: Mar. 31, 2024

(51) Int. Cl. H01L 23/522

(52) U.S. Cl. CPC H01L 23/5223; H10D 1/042; H10D 1/714; H10D 1/716

(57) ABSTRACT

A capacitor structure and methods for fabricating the same are provided. The capacitor structure includes a conductive wiring, a patterned barrier layer disposed on the conductive wiring and a trench capacitor disposed on the patterned barrier layer, wherein a first contact area between the conductive wiring and the patterned barrier layer is greater than a second contact area between the patterned barrier layer and the trench capacitor.

### BACKGROUND

Integrated chips are formed on semiconductor die including millions or billions of transistor devices. The transistor devices are configured to act as switches and/or to produce power gains so as to enable logical functionality for an integrated chip (e.g., form a processor configured to perform logic functions). Integrated chips also include passive devices, such as capacitors, resistors, inductors, varactors, etc. Therefore, the improved the capacitor and the improved process of fabricating the capacitors are desired as a development of a semiconductor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 9 illustrate the cross-sectional views of intermediate stages in the fabrication of a three-dimensional metal-insulator-metal (3D-MIM) capacitor structure embedded in an interconnect structure of a semiconductor wafer in accordance with some embodiments of the present application.

FIG. 10 and FIG. 11 illustrate the cross-sectional views of intermediate stages in the formation of the patterned barrier layer of the 3D-MIM capacitor structure in accordance with some alternative embodiments of the present application.

FIG. 12 through FIG. 14 illustrate the cross-sectional views of intermediate stages in the formation of the patterned barrier layer of the 3D-MIM capacitor structure in accordance with some alternative embodiments of the present application.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure and methods for fabricating a semiconductor die or a semiconductor wafer including the capacitor structure are provided. A patterned barrier layer is implemented or is formed over a conductive wiring (e.g., an interconnect wiring of an interconnect structure in the semiconductor die or semiconductor wafer) before forming a trench capacitor over the conductive wiring. Since the patterned barrier layer is formed outside the trench capacitor, the thickness uniformity of the patterned barrier layer is not significantly affected by the aspect ratio of the trench capacitor and the thickness uniformity of the patterned barrier layer can be well controlled. Accordingly, abnormalities in the trench capacitor related to the thickness uniformity of the patterned barrier layer can be reduced.

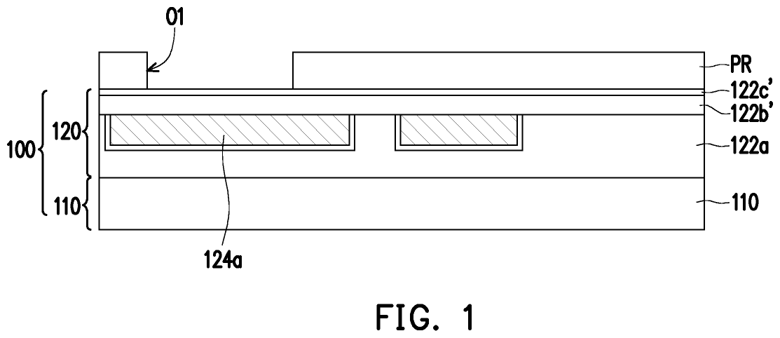

FIG. 1 through FIG. 9 illustrate the cross-sectional views of intermediate stages in the fabrication of a 3D-MIM capacitor structure embedded in an interconnect structure of a semiconductor wafer in accordance with some embodiments of the present application.

Referring to FIG. 1, a semiconductor substrate 110 of a semiconductor wafer 100 is provided. The semiconductor substrate 110 of the semiconductor wafer 100 may be or include a crystalline silicon substrate. The semiconductor substrate 110 may include various doped regions depending on design requirements (e.g., p-type substrate or n-type substrate). The doped regions may be doped with p-type or n-type dopants. In some embodiments, the doped regions are doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some other embodiments, the doped regions are configured for n-type planar-type Field Effect Transistors (FETs) and/or p-type planar-type FETs. In some alternative embodiments, the semiconductor substrate 110 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

An interconnect structure 120 of the semiconductor wafer 100 is then formed over the semiconductor substrate 110, and the fabrication process flow of the interconnect structure 120 will be described in accompany with FIG. 1 through FIG. 9.

As illustrated in FIG. 1, one or more stacked dielectric layers 122a and one or more interconnect wirings 124a of the interconnect structure 120 are formed on the semiconductor substrate 110. The interconnect wirings 124a are embedded in the stacked dielectric layers 122a and electrically connected to the semiconductor devices (e.g., planar-type FETs and/or FinFETs) formed in the semiconductor substrate 110. The stacked dielectric layers 122a and the interconnect wirings 124a of the interconnect structure 120 may be fabricated by back-end of line (BEOL) processes of the semiconductor wafer 100. The stacked dielectric layers 122a of the interconnect structure 120 may include one or more interlayered dielectric (ILD) layers, intermetal dielectric (IMD) layers, or the like. The material of the stacked dielectric layers 122a of the interconnect structure 120 may be or include silicon oxide (SiOₓ, where x>0), silicon nitride (SiNₓ, where x>0), silicon oxynitride (SiOₓN_{y}, where x>0 and y>0) or other suitable dielectric material. The interconnect wirings 124a of the interconnect structure 120 may be or include metallic wirings. The interconnect wirings 124a of the interconnect structure 120 may be or include copper wirings, copper pads, aluminum pads or combinations thereof. The stacked dielectric layers 122a of the interconnect structure 120 may be formed by chemical vapor deposition (CVD) process, physical vapor deposition (PVD) process, atomic layer deposition (ALD) process, some other deposition process, or a combination of the foregoing processes. The interconnect wirings 124a of the interconnect structure 120 may be formed by CVD process, PVD process, ALD process, sputtering process, electrochemical plating process, electroless plating process, some other deposition process, or a combination of the foregoing processes.

As shown in FIG. 1, the topmost layer of the interconnect wirings 124a is, for example, the fourth layer of conductive wirings or metallic interconnect wirings (M4) of the interconnect structure 120 count from bottom up. In other words, the first layer of metallic interconnect wirings (M1), the second layer of metallic interconnect wirings (M2) and the third layer of metallic interconnect wirings (M3) are sandwiched between the fourth layer of metallic interconnect wirings (M4) and the semiconductor substrate 110. However, the number of the layers of the stacked dielectric layers 122a as well as the number of the layers of the interconnect wirings 124a are merely described for illustration, and the present disclosure is not limited thereto.

An etch stop layer 122b of the interconnect structure 120 is formed on the stacked dielectric layers 122a and the interconnect wirings 124a, and a dielectric layer 122c of the interconnect structure 120 is then formed on the etch stop layer 122b. The material of the etch stop layer 122b is different from the material of the dielectric layer 122c. The material of the etch stop layer 122b may be or include silicon nitride (SiNₓ, where x>0), aluminum oxide compounds, such as AlOₓ, AlOC, AlON, and so on. The material of the dielectric layer 122c may be or include silicon oxide (SiOₓ, where x>0), silicon nitride (SiNₓ, where x>0), silicon oxynitride (SiOₓN_{y}, where x>0 and y>0) or other suitable dielectric material. The etch stop layer 122b and the dielectric layer 122c of the interconnect structure 120 may be formed by CVD process, PVD process, ALD process, some other deposition process, or a combination of the foregoing processes.

After depositing the etch stop layer 122b and the dielectric layer 122c, a patterned photoresist layer PR is formed on the dielectric layer 122c. The patterned photoresist layer PR is formed on the dielectric layer 122c through a spin-coating process, a baking process and the photolithography process, for example. As illustrated in FIG. 1, the patterned photoresist layer PR includes an opening O1 located above the interconnect wirings 124a. A portion of the dielectric layer 122c is revealed by the opening O1 of the patterned photoresist layer PR. The opening O1 of the patterned photoresist layer PR is utilized to define the position of the subsequently formed patterned barrier layer.

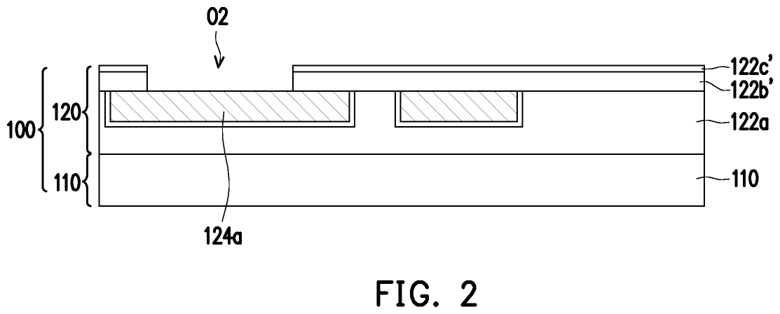

Referring to FIG. 1 and FIG. 2, the etch stop layer 122b and the dielectric layer 122c are patterned through an etch process by using the patterned photoresist layer PR as an etch mask. In other words, the dielectric layer 122c and the etch stop layer 122b are partially removed through the etch process until the top surface of the interconnect wirings 124a is revealed. The etch process may be performed by exposing the etch stop layer 122b and the dielectric layer 122c to an etchant. The etchant may include a dry etchant (e.g., a reactive ion etching (RIE) etchant, a plasma etchant, or the like). The etchant may have an etching chemistry including one or more tetrafluoromethane (CF₄), fluoroform (CHF₃), chlorine (Cl₂), nitrogen (N₂), argon (Ar), boron trichloride (BCl₃), or the like. A wet clean process may be performed to remove by-products derived from the etch process.

After performing the patterning process of the etch stop layer 122b and the dielectric layer 122c, a patterned etch stop layer 122b′ and a patterned dielectric layer 122c′ are formed, an opening O2 is formed in the patterned etch stop layer 122b′ and the patterned dielectric layer 122c′. The top surface of the interconnect wirings 124a is revealed by the opening O2, and the stacked dielectric layers 122a are not revealed from the opening O2. The number of the opening O2 defined in the patterned etch stop layer 122b′ and the patterned dielectric layer 122c′ is merely described for illustration, and the present disclosure is not limited thereto.

Furthermore, after performing the patterning process of the etch stop layer 122b and the dielectric layer 122c, any residual photoresist may be removed by an ash process or by dissolution with a solvent. In some embodiments, the etch process may be an anisotropic etching process.

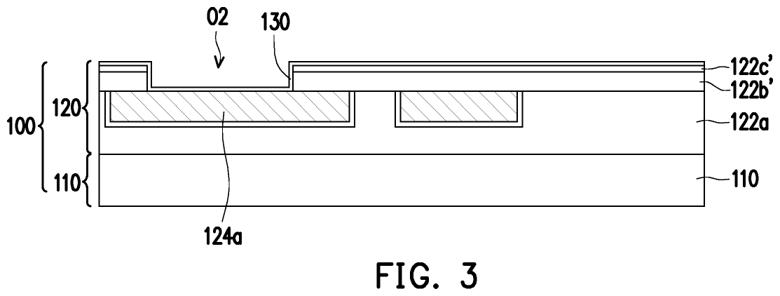

Referring to FIG. 3, a barrier material 130 is conformally formed over the semiconductor wafer 100 such that the patterned etch stop layer 122b′ and the patterned dielectric layer 122c′ are covered by the barrier material 130. The barrier material 130 is conformally deposited to cover the top surface of the patterned dielectric layer 122c′, the sidewalls of the patterned etch stop layer 122b′, the sidewalls of the patterned dielectric layer 122c′ and the portion of the top surface of the interconnect wirings 124a revealed by the opening O2. The barrier material 130 may be formed using a process such as chemical vapor deposition (CVD) process, physical vapor deposition (PVD) process, plasma enhanced CVD (PECVD) process, plasma enhanced physical vapor deposition (PEPVD) process, atomic layer deposition (ALD) process, combinations of the foregoing processes, or the like. The material of the barrier material 130 may be or include tantalum (Ta), tantalum nitride (TaN), titanium (Ti), titanium nitride (TiN), combinations of the foregoing materials, or the like.

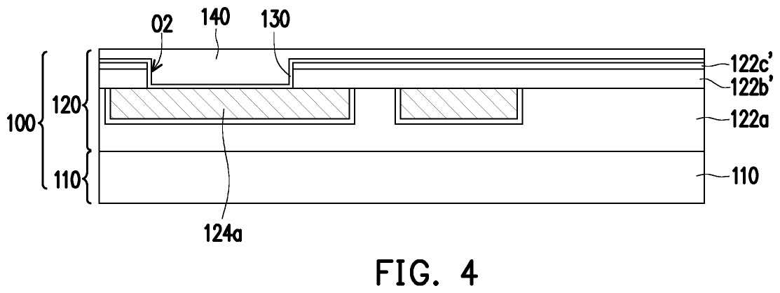

Referring to FIG. 4, a protection layer 140 is formed on the barrier material 130. The protection layer 140 may be or include photoresist material formed through a spin-coating process followed by a baking process. The protection layer 140 fills the opening O2, and the top surface of the protection layer 140 is substantial planar. In some other embodiments, the protection layer 140 includes inorganic dielectric material, metallic material, semiconductor material, a combination of the foregoing materials, or the like.

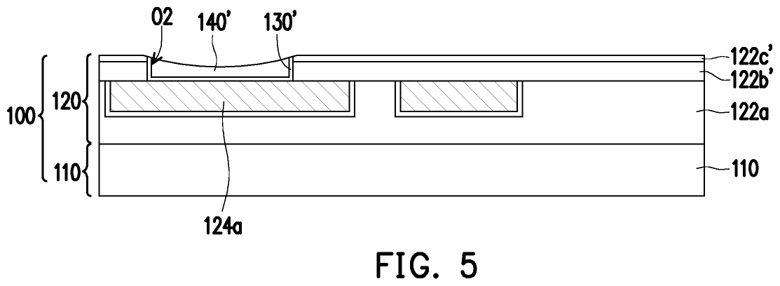

Referring to FIG. 4 and FIG. 5, a removal process is performed to partially remove the protection layer 140 and the barrier material 130 to form a patterned barrier layer 130′ and a protection layer 140′, wherein the protection layer 140′ is formed on the patterned barrier layer 130′ and remains in the opening O2 defined in the pattern etch stop layer 122b′ and the patterned dielectric layer 122c′. The removal process is performed to remove an excess portion of the protection layer 140 and an excess portion of the barrier material 130 until the top surface of the patterned dielectric layer 122c′ is revealed. The above-mentioned excess portion of the protection layer 140 and the above-mentioned excess portion of the barrier material 130 are referred as to portions of the protection layer 140 and portions of the barrier material 130 that are not located within the opening O2.

In some embodiments, the removal process of the protection layer 140 and the barrier material 130 includes an etch-back process. The etch-back process for partially removing the protection layer 140 and the barrier material 130 may be performed by exposing the protection layer 140 and the barrier material 130 to an etchant, wherein the etchant used in the etch-back process may etch the protection layer 140 faster than the barrier material 130. Due to the etch selectivity, as illustrated in FIG. 5, the protection layer 140′ may have a curved and recessed top surface, and the protection layer 140′ is wrapped by the patterned barrier layer 130′. The curved and recessed top surface of the protection layer 140′ is recessed from the top surface of the patterned dielectric layer 122c′. The patterned barrier layer 130′ may include a bottom plate portion and extending portions connected to the bottom plate portion, wherein the extending portions extend upwardly from an edge of the bottom plate portion. The bottom plate portion of the patterned barrier layer 130′ is in contact with the bottom surface of the protection layer 140′, and the extending portions of the patterned barrier layer 130′ is in contact with the sidewalls of the protection layer 140′. The protection layer 140′ is spaced apart from the interconnect wirings 124a by the bottom plate portion of the patterned barrier layer 130′. Furthermore, the protection layer 140′ is laterally spaced apart from the pattern etch stop layer 122b′ and the patterned dielectric layer 122c by the extending portions of the patterned barrier layer 130′.

In some alternative embodiments, the removal process of the protection layer 140 and the barrier material 130 includes a chemical mechanical polishing (CMP) process, a mechanical grinding process, a combination of the foregoing processes, or the like. Due to the polishing or grinding selectivity, as illustrated in FIG. 5, the protection layer 140′ may have a curved and recessed top surface, and the protection layer 140′ is wrapped by the patterned barrier layer 130′. The curved and recessed top surface of the protection layer 140′ is recessed from the top surface of the patterned dielectric layer 122c′. The curved and recessed top surface of the protection layer 140′ may have polishing marks or grinding marks thereon. The patterned barrier layer 130′ is in contact with the bottom surface of the protection layer 140′ as well as the sidewalls of the protection layer 140′. The protection layer 140′ is spaced apart from the interconnect wirings 124a by the patterned barrier layer 130′. Furthermore, the protection layer 140′ is laterally spaced apart from the pattern etch stop layer 122b′ by the patterned barrier layer 130′, and the protection layer 140′ is laterally spaced apart from the patterned dielectric layer 122c by the patterned barrier layer 130′.

As illustrated in FIG. 5, the extending portions of the patterned barrier layer 130′ laterally cover the sidewalls of the patterned etch stop layer 122b′, and the extending portions of the patterned barrier layer 130′ are laterally sandwiched between the protection layer 140′ and the patterned etch stop layer 122b′. The height of the extending portions of the patterned barrier layer 130′ may be greater than the thickness of the patterned etch stop layer 122b′. For example, the height of the extending portions of the patterned barrier layer 130′ is greater than the thickness of the patterned etch stop layer, and the height of the extending portion of the patterned barrier layer 130′ is less than the overall thickness of the patterned etch stop layer 122b′ and the patterned dielectric layer 122c′.

Since the protection layer 140′ has the curved and recessed top surface, the protection layer 140′ may have a central thickness (e.g., the minimum thickness) and a periphery thickness (e.g., the maximum thickness) greater than the central thickness, the height of the extending portions of the patterned barrier layer 130′ substantially equals to the periphery thickness of the protection layer 140′, and the height of the extending portions of the patterned barrier layer 130′ is greater than the central thickness of the protection layer 140′.

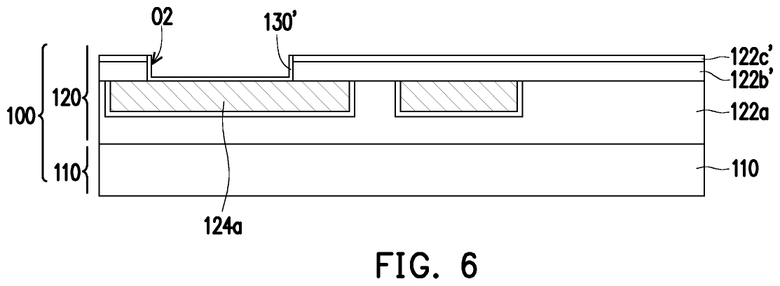

Referring to FIG. 6, after forming the patterned barrier layer 130′, the protection layer 140′ remained in the opening O2 is removed such that the patterned barrier layer 130′ distributed in the opening O2 is revealed. The removal process of the remaining protection layer 140′ may be or include an ash process or dissolution with a solvent.

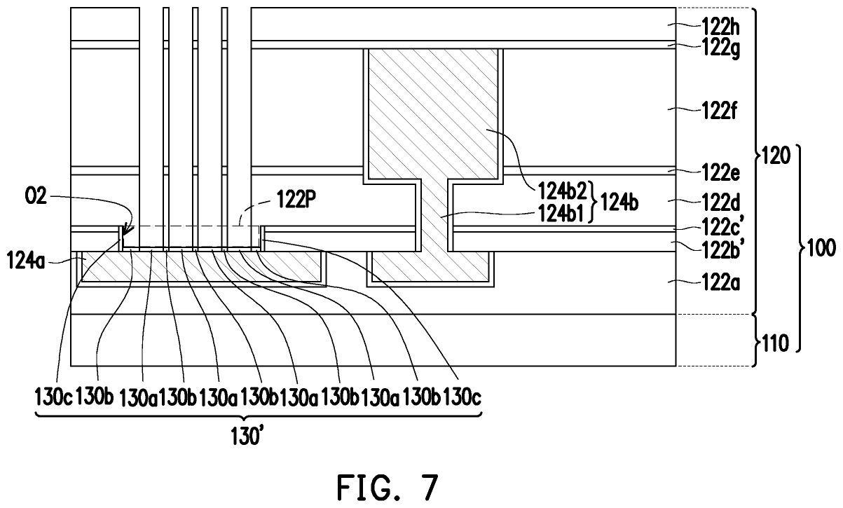

Referring to FIG. 7, after forming the patterned barrier layer 130′ on the interconnect wirings 124a, a dielectric layer 122d, an etch stop layer 122e and a dielectric layer 122f are sequentially formed over the patterned dielectric layer 122c′. The dielectric layer 122d may be deposited on the patterned dielectric layer 122c′ through CVD process, PVD process, ALD process, some other deposition process, or a combination of the foregoing processes. The etch stop layer 122e may be deposited on the dielectric layer 122d through CVD process, PVD process, ALD process, some other deposition process, or a combination of the foregoing processes. The dielectric layer 122f may be deposited on the etch stop layer 122e through CVD process, PVD process, ALD process, some other deposition process, or a combination of the foregoing processes. The material of the etch stop layer 122e is different from the material of the dielectric layer 122d and the dielectric layer 122f. The material of the dielectric layer 122d and the dielectric layer 122f may be or include silicon oxide (SiOₓ, where x>0), silicon nitride (SiNₓ, where x>0), silicon oxynitride (SiOₓN_{y}, where x>0 and y>0) or other suitable dielectric material. The material of the etch stop layer 122e may be or include silicon nitride (SiNₓ, where x>0), aluminum oxide compounds, such as AlOₓ, AlOC, AlON, and so on.

After forming the dielectric layer 122f, an interconnect wiring 124b including a via portion 124b1 and a wiring portion 124b2 is formed in the patterned etch stop layer 122b′, the patterned dielectric layer 122c′, the dielectric layer 122d, the etch stop layer 122e and the dielectric layer 122f. The interconnect wiring 124b including the via portion 124b1 and the wiring portion 124b2 may be formed through a dual-damascene process. The via portion 124b1 of the interconnect wiring 124b penetrates through the patterned etch stop layer 122b′, the patterned dielectric layer 122c′ and the dielectric layer 122d. The via portion 124b1 of the interconnect wiring 124b lands on and is electrically connected to the underlying interconnect wiring 124a. The wiring portion 124b2 of the interconnect wiring 124b penetrates through the etch stop layer 122e and the dielectric layer 122f. The wiring portion 124b2 is electrically connected to the via portion 124b1.

After forming the interconnect wiring 124b, an etch stop layer 122g and a dielectric layer 122h are sequentially formed over the dielectric layer 122f. The etch stop layer 122g may be deposited on the dielectric layer 122f through CVD process, PVD process, ALD process, some other deposition process, or a combination of the foregoing processes. The dielectric layer 122h may be deposited on the etch stop layer 122g through CVD process, PVD process, ALD process, some other deposition process, or a combination of the foregoing processes. The material of the etch stop layer 122g is different from the material of the dielectric layer 122h. The material of the etch stop layer 122g may be or include silicon nitride (SiNₓ, where x>0), aluminum oxide compounds, such as AlOₓ, AlOC, AlON, and so on. The material of the dielectric layer 122h may be or include silicon oxide (SiOₓ, where x>0), silicon nitride (SiNₓ, where x>0), silicon oxynitride (SiOₓN_{y}, where x>0 and y>0) or other suitable dielectric material.

As illustrated in FIG. 7, the dielectric layer 122d includes a dielectric protrusion 122P. The dielectric protrusion 122P protrudes from the bottom surface of the dielectric layer 122d downwardly as well as extends into the opening O2 defined in the patterned etch stop layer 122b′ and the patterned dielectric layer 122c′. That is, the dielectric protrusion 122P protrudes into the patterned etch stop layer 122b′. It is noted that the area where the opening O2 or the dielectric protrusion 122P is occupied can be referred as to a layout region for a trench capacitor.

The dielectric protrusion 122P of the dielectric layer 122d is wrapped by the patterned barrier layer 130′. The bottom plate portion of the patterned barrier layer 130′ is in contact with the bottom surface of the dielectric protrusion 122P, and the extending portions of the patterned barrier layer 130′ is in contact with the sidewalls of the dielectric protrusion 122P. The dielectric protrusion 122P is spaced apart from the underlying interconnect wirings 124a by the bottom plate portion of the patterned barrier layer 130′. Furthermore, the dielectric protrusion 122P is laterally spaced apart from the pattern etch stop layer 122b′ and the patterned dielectric layer 122c by the extending portions of the patterned barrier layer 130′.

As illustrated in FIG. 7, the extending portions of the patterned barrier layer 130′ are laterally sandwiched between the dielectric layer 122d and the patterned etch stop layer 122b′. The height of the extending portions of the patterned barrier layer 130′ may substantially equal to the thickness of the dielectric protrusion 122P of the dielectric layer 122d.

Multiple trenches TR are formed in the dielectric layer 122d, the etch stop layer 122e, the dielectric layer 122f, the etch stop layer 122g and the dielectric layer 122h such that multiple barrier regions of the patterned barrier layer 130′ are revealed by the trenches TR. The dielectric layer 122d, the etch stop layer 122e, the dielectric layer 122f, the etch stop layer 122g and the dielectric layer 122h are patterned by a photolithography process followed by an etch process, and a photomask is used in the photolithography process. In other words, a patterned photoresist layer (not shown) may be formed on the dielectric layer 122h through the photolithography process, and then the dielectric layer 122d, the etch stop layer 122e, the dielectric layer 122f, the etch stop layer 122g and the dielectric layer 122h are partially removed through the etch process until the barrier regions of the patterned barrier layer 130′ are revealed. The number of the trenches TR illustrated in FIG. 7 is merely described for illustration, and the present disclosure is not limited thereto.

Since the patterned barrier layer 130′ is formed over the interconnect wiring 124a before forming the trenches TR with high aspect ratio, the patterned barrier layer 130′ is not formed within the trenches TR with high aspect ratio and thus the thickness uniformity of the patterned barrier layer 130′ can be well controlled. Accordingly, abnormalities induced by the thickness uniformity of the patterned barrier layer can be minimized easily.

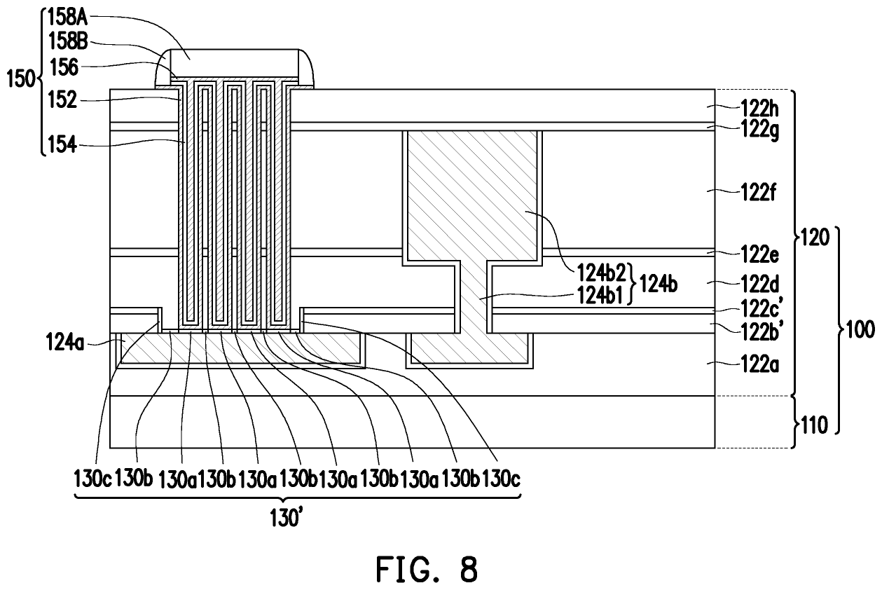

Referring to FIG. 8, after forming the trenches TR, a trench capacitor 150 is formed in the trenches TR. The trench capacitor 150 penetrates through the stacked dielectric layers including the dielectric layer 122d, the etch stop layer 122e, the dielectric layer 122f, the etch stop layer 122g and the dielectric layer 122h. As illustrated in FIG. 8, the trench capacitor 150 is disposed on the patterned barrier layer 130′ and is electrically connected to the underlying interconnect wiring 124a through the patterned barrier layer 130′, wherein a first contact area between the interconnect wiring 124a and the patterned barrier layer 130′ is greater than a second contact area between the patterned barrier layer 130′ and the trench capacitor 150. The patterned barrier layer 130′ may include one or more first barrier regions 130a and a second barrier region 130b, the first barrier regions 130a are sandwiched between the interconnect wiring 124a and the trench capacitor 150, and the second barrier region 130b is between the interconnect wiring 124a and stacked dielectric layers (i.e., the dielectric layer 122d, the etch stop layer 122e, the dielectric layer 122f, the etch stop layer 122g and the dielectric layer 122h). The above-mentioned first contact area is referred as to the sum of the contact area between the interconnect wiring 124a and the first barrier regions 130a as well as the contact area between the interconnect wiring 124a and the second barrier region 130b. The above-mentioned second contact area is referred as to the contact area between first barrier regions 130a and the trench capacitor 150. The patterned barrier layer 130′ may further includes one or more third barrier regions 130c connected to the second barrier region 130b, the third barrier regions 130c protrude upwardly into the dielectric layer 122d among the stacked dielectric layers, and the third barrier regions 130c are laterally spaced apart from the trench capacitor 150 by the dielectric layer 122d among the stacked dielectric layers. In some embodiments, as illustrated in FIG. 8, the third barrier regions 130c of the patterned barrier layer 130′ are laterally between the protrusion 122P of the dielectric layer 122d and the patterned etch stop layer 122b′. Furthermore, the height of the third barrier regions 130c of the patterned barrier layer 130′ is greater than the thickness of the patterned etch stop layer 122b′.

It is note that the first barrier regions 130a and the second barrier region 130b correspond to the bottom plate portion of the patterned barrier layer 130′ described in accompany with FIG. 7, and the third barrier regions 130c correspond to the extending portions of the patterned barrier layer 130′ described in accompany with FIG. 7.

In some embodiments, the trench capacitor 150 includes a first capacitor electrode layer 152, a capacitor dielectric layer 154 and a second capacitor electrode layer 156, wherein the first capacitor electrode layer 152 is disposed on and electrically connected to the interconnect wiring 124a through the patterned barrier layer 130′, the capacitor dielectric layer 154 is disposed on the first capacitor electrode layer 152, and the second capacitor electrode layer 156 is disposed on the capacitor dielectric layer 154. The first capacitor electrode layer 152 is in contact with the first barrier regions 130a of the patterned barrier layer 130′, and the first contact area between the interconnect wiring 124a and the first and second barrier regions 130a and 130b of the patterned barrier layer 130′ is greater than the second contact area between the first barrier regions 130a of the patterned barrier layer 130′ and the first capacitor electrode layer 152 of the trench capacitor 150.

The first capacitor electrode layer 152, the capacitor dielectric layer 154 and the second capacitor electrode layer 156 are deposited sequentially over the stacked dielectric layers including the dielectric layer 122d, the etch stop layer 122e, the dielectric layer 122f, the etch stop layer 122g and the dielectric layer 122h such that the trenches TR are filled by the trench capacitor 150. The first capacitor electrode layer 152 is conformally deposited in the trenches TR and covers the first barrier regions 130a of the patterned barrier layer 130′ through, for example, CVD process, PVD process, ALD process, sputtering process, electrochemical plating process, electroless plating process, some other deposition process, or a combination of the foregoing processes. The capacitor dielectric layer 154 is conformally deposited on the first capacitor electrode layer 152 through, for example, CVD process, PVD process, ALD process, some other deposition process, or a combination of the foregoing processes. The second capacitor electrode layer 156 is deposited on the capacitor dielectric layer 154 through, for example, CVD process, PVD process, ALD process, sputtering process, electrochemical plating process, electroless plating process, some other deposition process, or a combination of the foregoing processes. In order to pattern the capacitor dielectric layer 154 and the second capacitor electrode layer 156, a passivation structure 158A is formed on the second capacitor electrode layer 156, and a first patterning process (e.g. a photolithography process followed by an etch process) is performed to remove portions of the capacitor dielectric layer 154 and the second capacitor electrode layer 156 uncovered by the passivation structure 158A until the first capacitor electrode layer 152 is revealed. A pair of sidewall spacers 158B are then formed on sidewalls of the passivation structure 158A as well as portions of the revealed first capacitor electrode layer 152, and a second patterning process (e.g. a photolithography process followed by an etch process) is performed to remove portions of the first capacitor electrode layer 152 uncovered by the passivation structure 158A and the pair of sidewall spacers 158B until the dielectric layer 122h is revealed.

As illustrated in FIG. 8, the stacked dielectric layers including the dielectric layer 122d, the etch stop layer 122e, the dielectric layer 122f, the etch stop layer 122g and the dielectric layer 122h are in contact with the first capacitor electrode layer 152 of the trench capacitor 150 and the patterned barrier layer 130′. Furthermore, the first capacitor electrode layer 152 of the trench capacitor 150 is laterally spaced apart from the patterned etch stop layer 122b′ by the dielectric layer 122d and the third barrier regions 130c.

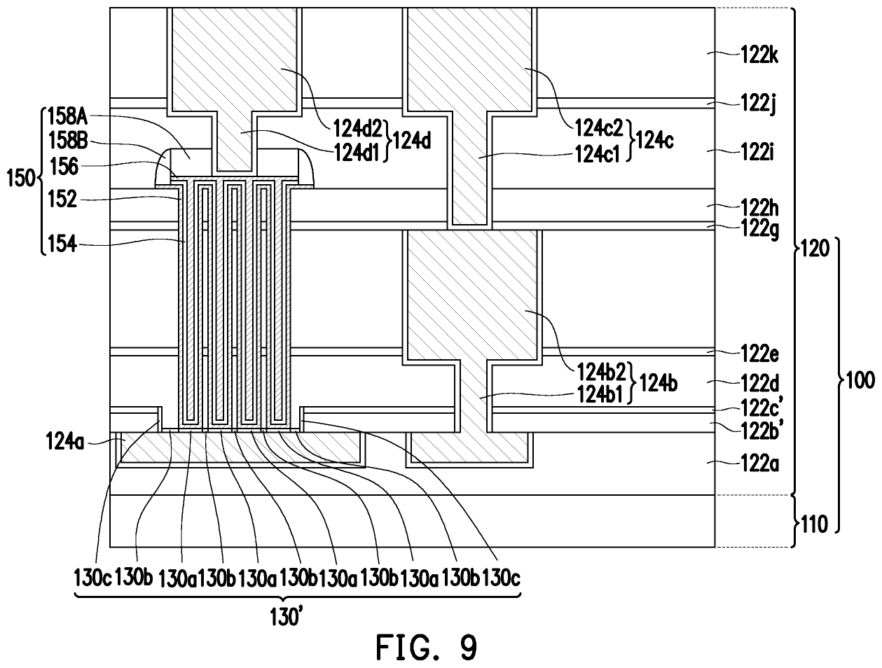

Referring to FIG. 9, after forming the trench capacitor 150, a dielectric layer 122i, an etch stop layer 122j and a dielectric layer 122k are sequentially formed over the patterned dielectric layer 122h. The dielectric layer 122i may be deposited on the patterned dielectric layer 122h through CVD process, PVD process, ALD process, some other deposition process, or a combination of the foregoing processes. The etch stop layer 122j may be deposited on the dielectric layer 122i through CVD process, PVD process, ALD process, some other deposition process, or a combination of the foregoing processes. The dielectric layer 122k may be deposited on the etch stop layer 122j through CVD process, PVD process, ALD process, some other deposition process, or a combination of the foregoing processes. The material of the etch stop layer 122j is different from the material of the dielectric layer 122i and the dielectric layer 122k. The material of the dielectric layer 122i and the dielectric layer 122k may be or include silicon oxide (SiOₓ, where x>0), silicon nitride (SiNₓ, where x>0), silicon oxynitride (SiOₓN_{y}, where x>0 and y>0) or other suitable dielectric material. The material of the etch stop layer 122j may be or include silicon nitride (SiNₓ, where x>0), aluminum oxide compounds, such as AlOₓ, AlOC, AlON, and so on.

After forming the dielectric layer 122k, an interconnect wiring 124c including a via portion 124cl and a wiring portion 124c2 and an interconnect wiring 124d including a via portion 124d1 and a wiring portion 124d2 are formed. The interconnect wiring 124c is formed in the patterned etch stop layer 122g, the dielectric layer 122h, the dielectric layer 122i, the etch stop layer 122j and the dielectric layer 122k. The interconnect wiring 124c including the via portion 124cl and the wiring portion 124c2 may be formed through a dual-damascene process. The via portion 124cl of the interconnect wiring 124c penetrates through the etch stop layer 122g, the dielectric layer 122h and the dielectric layer 122i. The via portion 124cl of the interconnect wiring 124c lands on and is electrically connected to the underlying interconnect wiring 124b. The wiring portion 124c2 of the interconnect wiring 124c penetrates through the etch stop layer 122j and the dielectric layer 122k. The wiring portion 124c2 is electrically connected to the via portion 124c1. The interconnect wiring 124d is formed in the dielectric layer 122i, the etch stop layer 122j and the dielectric layer 122k. The interconnect wiring 124d including the via portion 124d1 and the wiring portion 124d2 may be formed through a dual-damascene process. The via portion 124d1 of the interconnect wiring 124d penetrates through the dielectric layer 122i and the passivation structure 158A. The via portion 124d1 of the interconnect wiring 124d lands on and is electrically connected to the second capacitor electrode layer 156 of the trench capacitor 150. The wiring portion 124d2 of the interconnect wiring 124d penetrates through the etch stop layer 122j and the dielectric layer 122k. The wiring portion 124d2 is electrically connected to the via portion 124d1.

As illustrated in FIG. 9, in some embodiments, the interconnect structure 120 includes the stacked dielectric layers 122a, 122b′, 122c′ and 122d-122k, the interconnect wirings 124a-124d and the trench capacitor 150 electrically connected to the interconnect wirings 124a and 124d. The interconnect wirings 124a-124d and the trench capacitor 150 are embedded in the stacked dielectric layers 122a, 122b′, 122c′ and 122d-122k of the interconnect structure 120. Furthermore, the interconnect wirings 124a-124d are electrically connected to the semiconductor devices (e.g., planar-type FETs and/or FinFETs) formed in the substrate 110. The stacked dielectric layers 122a, 122b′, 122c′ and 122d-122k of the interconnect structure 120 may include one or more interlayered dielectric (ILD) layers, intermetal dielectric (IMD) layers, or the like. The material of the stacked dielectric layers 122a, 122b′, 122c′ and 122d-122k of the interconnect structure 120 may be or include silicon oxide (SiOₓ, where x>0), silicon nitride (SiNₓ, where x>0), silicon oxynitride (SiOₓN_{y}, where x>0 and y>0) or other suitable dielectric material. The interconnect wirings 124a-124d of the interconnect structure 120 may be or include metallic wirings. The interconnect wirings 124a-124d of the interconnect structure 120 may be or include copper wirings, copper pads, aluminum pads or combinations thereof.

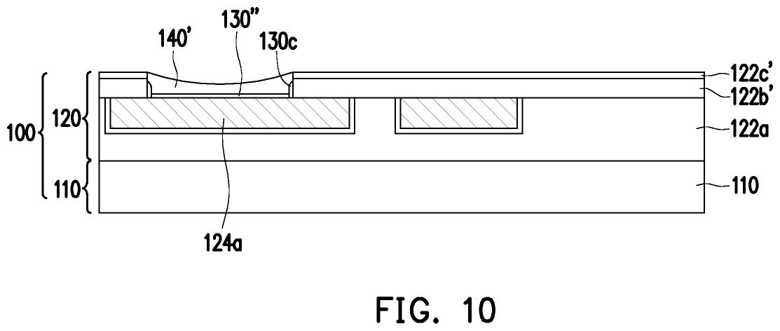

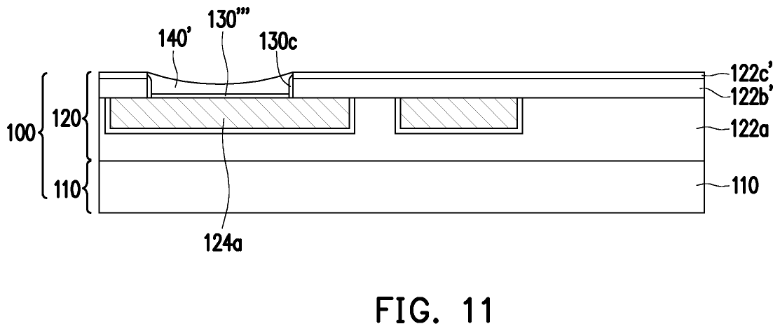

FIG. 10 and FIG. 11 illustrate the cross-sectional views of intermediate stages in the formation of the patterned barrier layer of the 3D-MIM capacitor structure in accordance with some alternative embodiments of the present application.

Referring to FIG. 5 and FIG. 10, the patterned barrier layer 130″ illustrated in FIG. 10 is similar with the patterned barrier layer 130′ illustrated in FIG. 5 except that the height of the third barrier regions 130c of the patterned barrier layer 130″ is less than the thickness of the patterned etch stop layer 122b′.

Referring to FIG. 5 and FIG. 11, the patterned barrier layer 130′″ illustrated in FIG. 11 is similar with the patterned barrier layer 130′ illustrated in FIG. 5 except that the height of the third barrier regions 130c of the patterned barrier layer 130′″ substantially equals to a thickness of the patterned etch stop layer 122b′.

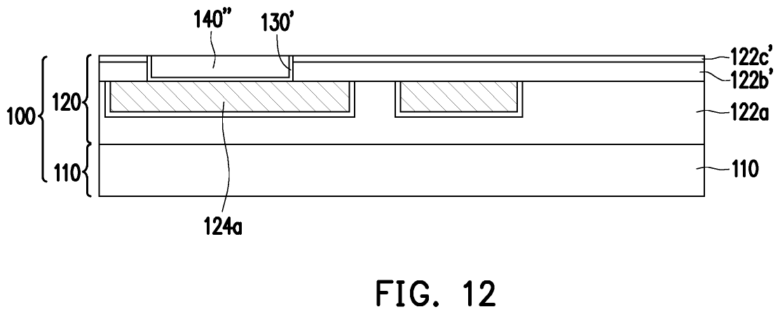

FIG. 12 through FIG. 14 illustrate the cross-sectional views of intermediate stages in the formation of the patterned barrier layer of the 3D-MIM capacitor structure in accordance with some alternative embodiments of the present application.

Referring to FIG. 5 and FIG. 12, the protection layer 140″ illustrated in FIG. 12 is similar with the protection layer 140′ illustrated in FIG. 5 except the protection layer 140″ includes a substantial planar top surface.

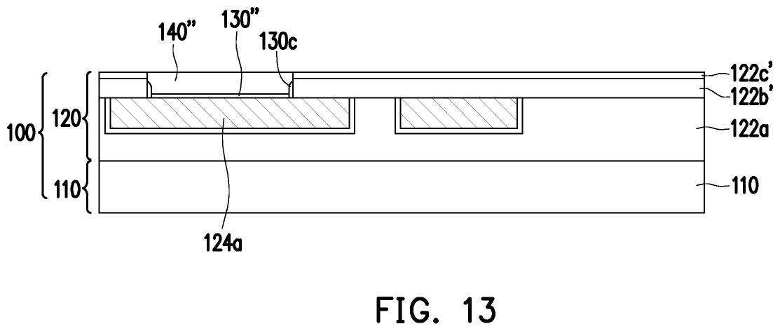

Referring to FIG. 10 and FIG. 13, the protection layer 140″ illustrated in FIG. 13 is similar with the protection layer 140′ illustrated in FIG. 10 except the protection layer 140″ includes a substantial planar top surface.

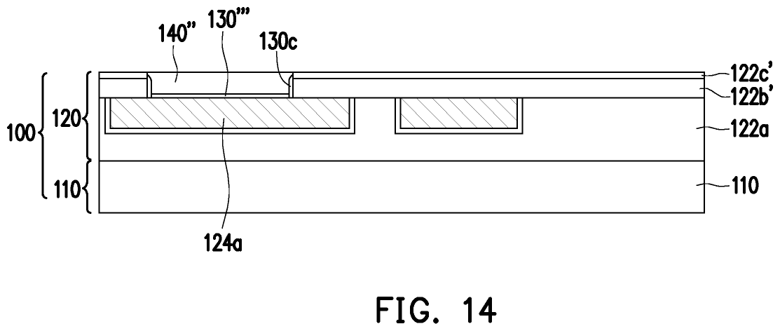

Referring to FIG. 11 and FIG. 14, the protection layer 140″ illustrated in FIG. 14 is similar with the protection layer 140′ illustrated in FIG. 11 except the protection layer 140″ includes a substantial planar top surface.

In the above-mentioned embodiments, since the patterned barrier layer is formed prior to the formation of the trench capacitor embedded in trenches with high aspect ratio, the patterned barrier layer may have uniform thickness and good step coverage. Accordingly, abnormalities resulted from the thickness uniformity of the patterned barrier layer can be reduced and reliability of the trench capacitor can be increased.

In accordance with some embodiments of the present disclosure, a capacitor structure is provided. The capacitor structure includes a conductive wiring, a patterned barrier layer disposed on the conductive wiring and a trench capacitor disposed on the patterned barrier layer, wherein a first contact area between the conductive wiring and the patterned barrier layer is greater than a second contact area between the patterned barrier layer and the trench capacitor. In some embodiments, the patterned barrier layer includes a first barrier region disposed between the conductive wiring and the trench capacitor. In some embodiments, the capacitor structure further includes stacked dielectric layers disposed on the conductive wiring and the pattern barrier layer, wherein the trench capacitor penetrates through the stacked dielectric layers. In some embodiments, the patterned barrier layer includes a first barrier region and a second barrier region, the first barrier region is between the conductive wiring and the trench capacitor, and the second barrier region is between the conductive wiring and the stacked dielectric layers. In some embodiments, the patterned barrier layer further includes a third barrier region connected to the second barrier region, the third barrier region protrudes into the stacked dielectric layers, and the third barrier region is laterally spaced apart from the trench capacitor by the stacked dielectric layers. In some embodiments, the stacked dielectric layers include a patterned etch stop layer and a dielectric layer, the patterned etch stop layer covers the conductive wiring, the dielectric layer covers the patterned etch stop layer, and the dielectric layer includes a protrusion protruding into the patterned etch stop layer. In some embodiments, the third barrier region of the patterned barrier layer is laterally between the protrusion of the dielectric layer and the patterned etch stop layer. In some embodiments, the trench capacitor includes: a first capacitor electrode layer disposed on and electrically connected to the conductive wiring through the patterned barrier layer; a capacitor dielectric layer disposed on the first capacitor electrode layer; and a second capacitor electrode layer disposed on the capacitor dielectric layer, wherein the first capacitor electrode layer is in contact with the patterned barrier layer, and the first contact area between the conductive wiring and the patterned barrier layer is greater than the second contact area between the patterned barrier layer and the first capacitor electrode layer of the trench capacitor.

In accordance with some embodiments of the present disclosure, a capacitor structure is provided. The capacitor structure includes a conductive wiring, tacked dielectric layers disposed on the conductive wiring, a patterned barrier layer embedded in the stacked dielectric layers and a trench capacitor. The stacked dielectric layers include a patterned etch stop layer and a dielectric layer, the patterned etch stop layer covering the conductive wiring, the dielectric layer covering the patterned etch stop layer, and the dielectric layer includes a protrusion protruding into the patterned etch stop layer. A portion of the patterned barrier layer is laterally between the protrusion and the patterned etch stop layer, and the trench capacitor penetrates through the stacked dielectric layers and is disposed on the patterned barrier layer. In some embodiments, the protrusion of the dielectric layer is wrapped by the patterned barrier layer. In some embodiments, the stacked dielectric layers are in contact with the trench capacitor and the patterned barrier layer. In some embodiments, a height of the portion of the patterned barrier layer is greater than a thickness of the patterned etch stop layer. In some embodiments, a height of the portion of the patterned barrier layer is less than a thickness of the patterned etch stop layer. In some embodiments, a height of the portion of the patterned barrier layer substantially equals to a thickness of the patterned etch stop layer. In some embodiments, the protrusion of the dielectric layer is spaced apart from the conductive wiring by the patterned barrier layer. In some embodiments, the trench capacitor includes: a first capacitor electrode layer disposed on and electrically connected to the conductive wiring through the patterned barrier layer; a capacitor dielectric layer disposed on the first capacitor electrode layer; and a second capacitor electrode layer disposed on the capacitor dielectric layer, wherein the first capacitor electrode layer is in contact with the patterned barrier layer and the dielectric layer of the stacked dielectric layers, and the first capacitor electrode layer is spaced apart from the patterned etch stop layer.

In accordance with some embodiments of the present disclosure, a method for fabricating a capacitor structure is provided. A patterned etch stop layer and a first dielectric layer are formed on a conductive wiring, wherein the patterned etch stop layer and the first dielectric layer include an opening revealing a portion of the conductive wiring. A patterned barrier layer is formed on the portion of the conductive wiring and in the opening. After forming the patterned barrier layer, a second dielectric layer is formed on the first dielectric layer. A trench capacitor is formed in the first dielectric layer and the second dielectric layer, wherein the trench capacitor is electrically connected to the conductive wiring through the patterned barrier layer. In some embodiments, the forming of the patterned barrier layer includes: forming a barrier material conformally covering the patterned etch stop layer and the first dielectric layer; forming a protection layer on the barrier material; and partially removing the protection layer and the barrier material to form the patterned barrier layer on the portion of the conductive wiring and in the opening. In some embodiments, partially removing the protection layer and the barrier material includes an etch process. In some embodiments, partially removing the protection layer and the barrier material comprises a chemical mechanical polishing process. In some embodiments, the forming of the patterned barrier layer further includes: after partially removing the protection layer and the barrier material, removing the protection layer remained in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor structure, comprising:
a conductive wiring;
a patterned barrier layer disposed on the conductive wiring; and
a trench capacitor disposed on the patterned barrier layer, wherein a first contact area between the conductive wiring and the patterned barrier layer is greater than a second contact area between the patterned barrier layer and the trench capacitor.

2. The capacitor structure of claim 1, wherein the patterned barrier layer comprises a first barrier region disposed between the conductive wiring and the trench capacitor.

3. The capacitor structure of claim 1 further comprising:
stacked dielectric layers disposed on the conductive wiring and the pattern barrier layer, wherein the trench capacitor penetrates through the stacked dielectric layers.

4. The capacitor structure of claim 3, wherein the patterned barrier layer comprises a first barrier region and a second barrier region, the first barrier region is between the conductive wiring and the trench capacitor, and the second barrier region is between the conductive wiring and the stacked dielectric layers.

5. The capacitor structure of claim 4, wherein the patterned barrier layer further comprises a third barrier region connected to the second barrier region, the third barrier region protrudes into the stacked dielectric layers, and the third barrier region is laterally spaced apart from the trench capacitor by the stacked dielectric layers.

6. The capacitor structure of claim 5, wherein the stacked dielectric layers comprise a patterned etch stop layer and a dielectric layer, the patterned etch stop layer covers the conductive wiring, the dielectric layer covers the patterned etch stop layer, and the dielectric layer comprises a protrusion protruding into the patterned etch stop layer.

7. The capacitor structure of claim 6, wherein the third barrier region of the patterned barrier layer is laterally between the protrusion of the dielectric layer and the patterned etch stop layer.

8. The capacitor structure of claim 1, wherein the trench capacitor comprises:
a first capacitor electrode layer disposed on and electrically connected to the conductive wiring through the patterned barrier layer;
a capacitor dielectric layer disposed on the first capacitor electrode layer; and
a second capacitor electrode layer disposed on the capacitor dielectric layer, wherein the first capacitor electrode layer is in contact with the patterned barrier layer, and the first contact area between the conductive wiring and the patterned barrier layer is greater than the second contact area between the patterned barrier layer and the first capacitor electrode layer of the trench capacitor.

9. A capacitor structure, comprising:
a conductive wiring;
stacked dielectric layers disposed on the conductive wiring, the stacked dielectric layers comprising a patterned etch stop layer and a dielectric layer, the patterned etch stop layer covering the conductive wiring, the dielectric layer covering the patterned etch stop layer, and the dielectric layer comprising a protrusion protruding into the patterned etch stop layer;
a patterned barrier layer embedded in the stacked dielectric layers, wherein a portion of the patterned barrier layer is laterally between the protrusion and the patterned etch stop layer; and
a trench capacitor penetrating through the stacked dielectric layers and disposed on the patterned barrier layer.

10. The capacitor structure of claim 9, wherein the protrusion of the dielectric layer is wrapped by the patterned barrier layer.

11. The capacitor structure of claim 9, wherein the stacked dielectric layers are in contact with the trench capacitor and the patterned barrier layer.

12. The capacitor structure of claim 9, wherein a height of the portion of the patterned barrier layer is greater than a thickness of the patterned etch stop layer.

13. The capacitor structure of claim 9, wherein a height of the portion of the patterned barrier layer is less than a thickness of the patterned etch stop layer.

14. The capacitor structure of claim 9, wherein a height of the portion of the patterned barrier layer substantially equals to a thickness of the patterned etch stop layer.

15. The capacitor structure of claim 9, wherein the protrusion of the dielectric layer is spaced apart from the conductive wiring by the patterned barrier layer.

16. A method, comprising:
forming a patterned etch stop layer and a first dielectric layer on a conductive wiring, the patterned etch stop layer and the first dielectric layer comprising an opening revealing a portion of the conductive wiring;
forming a patterned barrier layer on the portion of the conductive wiring and in the opening;
after forming the patterned barrier layer, forming a second dielectric layer on the first dielectric layer;
forming a trench capacitor in the first dielectric layer and the second dielectric layer, wherein the trench capacitor is electrically connected to the conductive wiring through the patterned barrier layer.

17. The method of claim 16, wherein forming the patterned barrier layer comprises:
forming a barrier material conformally covering the patterned etch stop layer and the first dielectric layer;
forming a protection layer on the barrier material; and
partially removing the protection layer and the barrier material to form the patterned barrier layer on the portion of the conductive wiring and in the opening.

18. The method of claim 17, wherein partially removing the protection layer and the barrier material comprises an etch process.

19. The method of claim 17, wherein partially removing the protection layer and the barrier material comprises a chemical mechanical polishing process.

20. The method of claim 17, wherein forming the patterned barrier layer further comprises
after partially removing the protection layer and the barrier material, removing the protection layer remained in the opening.
